(19) United States
(12) Patent Application Publication
(10) Pub. No.: US 2025/0275420 A1
(43) Pub. Date: Aug. 28, 2025

(54) DISPLAY DEVICE

(71) Applicant: LG Display Co., Ltd., Seoul (KR)

(72) Inventor: SeungHan LEE, Paju-si (KR)

(21) Appl. No.: 18/755,351

(22) Filed: Jun. 26, 2024

(30) Foreign Application Priority Data
Feb. 27, 2024 (KR) 10-2024-0028164

(51) Int. Cl. H10K 59/80

(52) U.S. Cl. CPC H10K 59/873

(57) ABSTRACT

According to an aspect of the present disclosure, there is provided a display device. The display device includes a substrate which includes a display area and a non-display area adjacent to the display area, a light emitting element such as a light emitting diode on the display area, a first inorganic encapsulation layer on the light emitting element, an organic encapsulation layer on the first inorganic encapsulation layer, a second inorganic encapsulation layer on the organic encapsulation layer, and an optical compensation layer, which is disposed on or below the second inorganic encapsulation layer, and includes or is formed of a transition metal oxide. Therefore, it can reduce or minimize the oxidation of the second inorganic encapsulation layer and suppress occurrence of an afterimage.

### CROSS-REFERENCE TO RELATED APPLICATIONS

This application claims the priority of Korean Patent Application No. 10-2024-0028164 filed on Feb. 27, 2024 in the Korean Intellectual Property Office, the disclosure of which is incorporated herein by reference.

### BACKGROUND

### Technical Field

The present disclosure relates to a display device, and more particularly, to a display device having an enhanced reliability.

### Description of the Related Art

As information society develops, needs for display devices to display images are increased in various manners. According to this, various display devices such as a liquid crystal display (LCD) device, a plasma display panel (PDP) device, an organic light emitting display (OLED) device, and a quantum dot light emitting display (QLED) device have been recently utilized.

Among these display devices, an organic light emitting display device can be manufactured with a light weight and a small thickness, because it does not require an additional light source unlike a liquid crystal display device. Further, the organic light emitting display device is advantageous in terms of power consumption due to a low voltage driving, and is excellent in color implementation, a response speed, a viewing angle and a contrast ratio (CR). Accordingly, the organic light emitting display device is being researched as a next generation display device.

### BRIEF SUMMARY

Various embodiments of the present disclosure provide a display device in which occurrence of an afterimage on the display device (for example, a display panel thereof) is reduced or minimized.

Various embodiments of the present disclosure provide a display device in which a non-uniform state of brightness of the display device (for example, a display panel thereof) is reduced or minimized.

The technical benefits to be achieved by the present disclosure, the means for achieving the benefits, and the effects of the present disclosure described above do not specify essential features of the claims, and, thus, the scope of the claims is not limited to the disclosure of the present disclosure.

According to an aspect of the present disclosure, there is provided a display device. The display device comprises a substrate which includes a display area and a non-display area surrounding the display area; a light emitting element (for example, a light emitting diode, especially an organic light emitting diode, but not limited thereto) on the display area (or disposed at the display area); a first inorganic encapsulation layer on the light emitting element; an organic encapsulation layer on the first inorganic encapsulation layer; a second inorganic encapsulation layer on the organic encapsulation layer; and an optical compensation layer, which is disposed on or below the second inorganic encapsulation layer, and includes or be formed of a transition metal oxide (in other words, an oxide of a transition metal). Therefore, it can be reducing or minimizing the occurrence of an afterimage of a display device (or a display panel thereof) due to oxidation by light emitted from the light emitting element (for example, the light-emitting diode).

Other detailed matters of the exemplary embodiments are included in the detailed description and the drawings.

According to the present disclosure, an optical compensation layer is disposed (or included) on an upper side or a lower side of a second inorganic encapsulation layer, thereby reducing or minimizing oxidation of the second inorganic encapsulation layer.

According to the present disclosure, oxidation of the second inorganic encapsulation layer is reduced or minimized, thereby reducing or minimizing occurrence of an afterimage on a display device due to the oxidation of the second inorganic encapsulation layer.

According to the present disclosure, a non-uniform state of brightness of a display device due to partial oxidation of a second inorganic encapsulation layer is reduced or minimized, thereby enhancing a display quality of a display device.

According to the present disclosure, a moisture proof function of a display device is enhanced, thereby improving the reliability of the display device.

The effects according to the present disclosure are not limited to the contents exemplified above, and further various effects may be provided in the present disclosure.

The effects of the present disclosure are not limited to the aforementioned effects, and other various effects are included in the detailed description and the drawings.

### BRIEF DESCRIPTION OF THE SEVERAL VIEWS OF THE DRAWINGS

FIG. 1 is a schematic plan view of a display device according to an exemplary embodiment of the present disclosure.

FIG. 2 is a cross-sectional view taken along the line II-II′ of FIG. 1.

FIG. 3 is a cross-sectional view taken along the line III-III′ of FIG. 1.

FIG. 4 is a cross-sectional view of a display device according to another exemplary embodiment of the present disclosure.

FIG. 5 is a cross-sectional view of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next to,” one or more parts may be positioned between the two parts unless the terms are used with the term “immediately” or “directly.”

When an element or layer is disposed “on” another element or layer, yet another element or layer may be interposed directly on the another element or layer therebetween.

Although the terms “first,” “second,” and the like are used for describing various components, these components are not confined by these terms. These terms are merely used for distinguishing one component from other components. Therefore, a first component to be mentioned below may be a second component in a technical concept of the present disclosure.

Like reference numerals generally denote like elements throughout the description.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

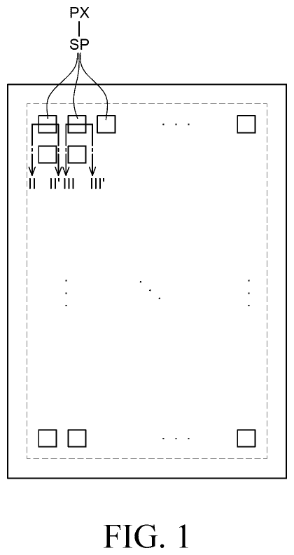

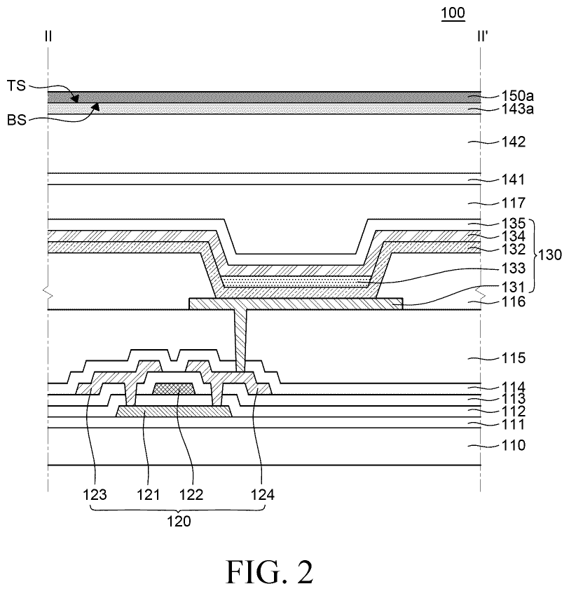

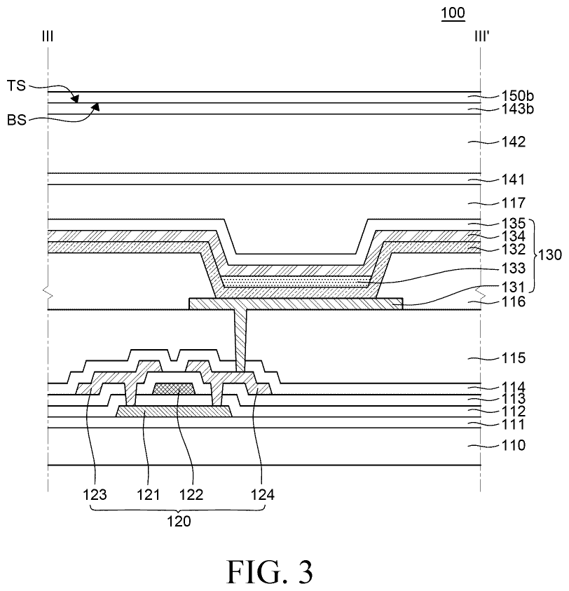

FIG. 1 is a schematic plan view of a display device according to an exemplary embodiment of the present disclosure, FIG. 2 is a cross-sectional view taken along the line II-II′ of FIG. 1, and FIG. 3 is a cross-sectional view taken along the line III-III′ of FIG. 1. A sub pixel SP of FIG. 2 shows a sub pixel SP of an initial state, or an almost non-light emission state of a display device 100, and a sub pixel SP of FIG. 3 shows a sub pixel SP of a light emission state for a significantly long time of the display device 100.

Referring to FIGS. 1 to 3, the display device 100 (or as well known in the art, a display panel thereof) includes a substrate 110, a transistor 120, a light emitting diode 130, a first inorganic encapsulation layer 141, an organic encapsulation layer 142, second inorganic encapsulation layers 143a and 143b, and optical compensation layers 150a and 150b.

Referring to FIG. 1, the substrate 110 is configured to support and protect a plurality of components of the display device 100. The substrate 110 may be formed of a plastic material having flexibility. Alternatively, the substrate 110 may be formed of an insulating material having transparency. For instance, the substrate 110 may be formed of a transparent polyimide (PI).

The substrate 110 includes a display area AA and a non-display area NA.

The display area AA may be disposed at a central portion of the substrate 110, and may be an area in which an image is displayed in the display device 100. A light emitting element (or display element) and various driving elements for driving the light emitting element (or display element) may be disposed in the display area AA. For instance, as shown in FIGS. 2 and 3, the light emitting element (or display element) may be configured as a light emitting diode 130 including a first electrode 131, a light emitting unit 133 and a second electrode 135. Also, various driving elements such as a transistor 120 for driving the light emitting element (or display element), a capacitor and wiring lines may be disposed at the display area AA.

A plurality of pixels PX may be disposed at the display area AA. The plurality of pixels PX may be disposed at intersections between a plurality of gate lines disposed in a first direction, and a plurality of data lines disposed in a second direction different from the first direction. Here, the first direction may be a horizontal direction of FIG. 1 and the second direction may be a vertical direction of FIG. 1, but are not limited thereto. Each of the plurality of pixels PX may include a plurality of sub pixels SP for emitting light of different colors, respectively. For instance, some of the plurality of sub pixels SP may be red sub pixels, some of the plurality of sub pixels SP may be green sub pixels, and others of the plurality of sub pixels SP may be blue sub pixels. The plurality of sub pixels SP may further include white sub pixels, and the present disclosure is not limited thereto.

The pixel PX is a minimum unit which constitutes a screen, and each of the plurality of pixels PX may include a light emitting diode 130 and a driving element. The driving element may include a switching transistor, a driving transistor, etc. The driving element may be electrically connected to signal lines such as gate lines and data lines connected to a gate driver, a data driver, and the like disposed at a non-display area NA.

The non-display area NA may be an area disposed at a peripheral area of the substrate 110, in other words, an area where an image is not displayed. The non-display area NA may be disposed to surround the display area AA. Various components for driving a plurality of pixels PX disposed at the display area AA may be disposed at the non-display area NA. For instance, a driving integrated circuit IC to supply a signal for driving the plurality of pixels PX, a driving circuit, a signal line, a flexible film, etc. may be disposed. The driving integrated circuit IC may include a gate driver, a data driver, etc. The driving integrated circuit IC and the driving circuit may be disposed in a GIP (gate in panel) manner, a COF (chip on film) manner, a TAB (tape automated bonding) manner, a TCP (tape carrier package) manner, a COG (chip on glass) manner, or the like.

Hereinafter, each of the plurality of sub pixels SP disposed at the display area AA of the display device 100 will be explained in more detail with reference to FIGS. 2 and 3.

Referring to FIGS. 2 and 3, a buffer layer 111 may be disposed on the substrate 110. The buffer layer 111 may be configured to enhance a bonding force between layers formed on the buffer layer 111 and the substrate 110. Further, the buffer layer 111 may block alkali components, etc. leaking from the substrate 110, and may suppress spread of moisture and/or oxygen introduced from the outside of the substrate 110. The buffer layer 111 may be formed of a single layer of silicon nitride (SiNx) or silicon oxide (SiOx), or multi-layers thereof. However, the present disclosure is not limited thereto. Alternatively, the buffer layer 111 may be omitted based on a type and a material of the substrate 110, a structure and a type of the transistor 120, etc.

The transistor 120 may be disposed on the buffer layer 111, thereby driving the light emitting diode 130. The transistor 120 may be disposed at each of the plurality of sub pixels SP of the display area AA. The transistor 120 disposed at each of the plurality of sub pixels SP may be used as a driving element of the display device 100. For instance, the transistor 120 may be a thin film transistor (TFT), an N-channel metal oxide semiconductor (NMOS) transistor, a P-channel metal oxide semiconductor (PMOS) transistor, a complementary metal oxide semiconductor (CMOS) transistor, a field effect transistor (FET), etc. However, the present disclosure is not limited thereto. Hereinafter, the present disclosure will be explained under an assumption that the transistor 120 is a thin film transistor, but is not limited thereto.

The transistor 120 may include an active layer 121, a gate electrode 122, a source electrode 123 and a drain electrode 124. The transistor 120 of FIGS. 2 and 3 is a thin film transistor of a top gate structure where the gate electrode 122 is disposed on the active layer 121. However, the present disclosure is not limited thereto, but may be configured as a thin film transistor of a bottom gate structure.

The active layer 121 of the transistor 120 may be disposed on the buffer layer 111. The active layer 121 is an area where a channel is formed at the time of the transistor 120 being driven. The active layer 121 may be formed of an oxide semiconductor, amorphous silicon (a-Si), polycrystalline silicon (poly-Si), an organic semiconductor, etc., but the present disclosure is not limited thereto.

A gate insulating layer 112 may be disposed above the active layer 121. The gate insulating layer 112 may be formed of a single layer of silicon nitride (SiNx) or silicon oxide (SiOx), which is an inorganic material, or multi-layers thereof. Contact holes for contacting the source electrode 123 and the drain electrode 124 to a source region and a drain region of the active layer 121, respectively may be formed in the gate insulating layer 112. As shown in FIGS. 2 and 3, the gate insulating layer 112 may be formed over an entire surface of the substrate 110, and may also be patterned to have the same width as the gate electrode 122. However, the present disclosure is not limited thereto.

The gate electrode 122 may be disposed on the gate insulating layer 112. The gate electrode 122 may be disposed on the gate insulating layer 112 so as to overlap a channel region of the active layer 121. The gate electrode 122 may be formed of one of various metallic materials, for instance, molybdenum (Mo), aluminum (Al), chrome (Cr), gold (Au), titanium (Ti), nickel (Ni), neodymium (Nd) and copper (Cu). Alternatively, the gate electrode 122 may be formed of an alloy of two or more of these metallic materials, or a multi-layer thereof, but the present disclosure is not limited thereto.

An interlayer insulating layer 113 may be disposed on the gate electrode 122. The interlayer insulating layer 113 may be formed of a single layer of silicon nitride (SiNx) or silicon oxide (SiOx), which is an inorganic material, or multi-layers thereof. Contact holes for contacting the source electrode 123 and the drain electrode 124 to the source region and the drain region of the active layer 121, respectively may be formed in the interlayer insulating layer 113.

The source electrode 123 and the drain electrode 124 may be disposed on the interlayer insulating layer 113. The source electrode 123 and the drain electrode 124 may be electrically connected to the active layer 121 via the contact holes of the gate insulating layer 112 and the interlayer insulating layer 113. The source electrode 123 and the drain electrode 124 may be formed of one of various metallic materials, for instance, molybdenum (Mo), aluminum (Al), chrome (Cr), gold (Au), titanium (Ti), nickel (Ni), neodymium (Nd) and copper (Cu). Alternatively, the source electrode 123 and the drain electrode 124 may be formed of an alloy of two or more of these metallic materials, or a multi-layer thereof, but the present disclosure is not limited thereto.

For convenience of explanation, FIGS. 2 and 3 illustrate only a driving transistor among the various types of transistors 120 included in the display device 100. However, other transistors such as a switching transistor may be disposed.

A passivation layer 114 for protecting the transistor 120 may be disposed on the transistor 120. A contact hole for exposing the drain electrode 124 of the transistor 120 may be formed in the passivation layer 114. FIGS. 2 and 3 illustrate that a contact hole for exposing the drain electrode 124 is formed in the passivation layer 114. However, a contact hole for exposing the source electrode 123 may be formed in the passivation layer 114. The passivation layer 114 may be configured as a single layer of silicon nitride (SiNx) or silicon oxide (SiOx), or a multi-layer thereof. However, the passivation layer 114 may be omitted according to an exemplary embodiment of the present disclosure.

An over coating layer 115 for planarizing an upper portion of the transistor 120 may be disposed on the passivation layer 114. A contact hole for exposing the drain electrode 124 of the transistor 120 may be formed in the over coating layer 115. FIGS. 2 and 3 illustrate that a contact hole for exposing the drain electrode 124 is formed in the over coating layer 115. However, a contact hole for exposing the source electrode 123 may be formed in the over coating layer 115. The over coating layer 115 may be formed of one of acryl resin, epoxy resin, phenol resin, polyamide resin, polyimide resin, unsaturated polyester resin, polyphenylene resin, polyphenylene sulfide resin, benzocyclobutene and photoresist. However, the present disclosure is not limited thereto.

The light emitting diode 130 may be disposed on the over coating layer 115. The light emitting diode 130 includes a first electrode 131 formed on the over coating layer 115 and electrically connected to the drain electrode 124 of the transistor 120, a hole transport layer (HTL) 132 disposed on the first electrode 131, a light emitting unit 133 disposed on the hole transport layer 132, an electron transport layer (ETL) 134 disposed on the light emitting unit 133, and a second electrode 135 disposed on the electron transport layer 134.

The first electrode 131 may be disposed on the over coating layer 115. The first electrode 131 may be an anode electrode configured to supply a hole to the light emitting unit 133, but the present disclosure is not limited thereto. The first electrode 131 may be electrically connected to the transistor 120 via the contact hole of the over coating layer 115. For instance, although not shown in FIGS. 2 and 3, the first electrode 131 may be electrically connected to the source electrode 123 of the transistor 120. The first electrodes 131 may be disposed to be spaced from each other according to each sub pixel SP. The first electrode 131 may be formed of a transparent conductive material. For instance, the first electrode 131 may be formed of indium tin oxide (ITO), indium zin oxide (IZO), etc., but the present disclosure is not limited thereto.

Although not shown in the drawings, in a case that the display device 100 according to an exemplary embodiment of the present disclosure is a top emission type which is a top light emitting type, the first electrode 131 may further include a reflection layer so that light emitted from the light emitting unit 133 may be emitted more smoothly in an upward direction by being reflected by the first electrode 131. For instance, the first electrode 131 may have a two-layer structure in which a transparent conductive layer formed of a transparent conductive material and a reflection layer are sequentially laminated on each other, or may have a three-layer structure in which a transparent conductive layer, a reflection layer and a transparent conductive layer are sequentially laminated on each other. The reflection layer may be formed of silver (Ag) or an alloy including silver, and may be formed of silver or APC (Ag/Pd/Cu) for instance.

A bank 116 may be disposed on the first electrode 131 and the over coating layer 115. The bank 116 may be configured to divide adjacent sub pixel regions from each other. Also, the bank 116 may be configured to divide pixel PX regions from each other, the pixel region consisting of regions of a plurality of sub pixels SP.

The hole transport layer 132 may be disposed on the first electrode 131. The hole transport layer 132 may be disposed on the first electrode 131 and the bank 116 so as to cover them. The hole transport layer 132 may be an organic layer for smoothly transferring a hole to the light emitting unit 133, and may be disposed on the first electrode 131 and the bank 116 as a single layer. For instance, the hole transport layer 132 may be formed of at least one selected from a group consisting of NPD(N,N′-bis(naphthalene-1-yl)-N,N′-bis(phenyl)-2,2′-dimethylbenzidine), TPD(N,N′-bis-(3-methylphenyl)-N,N′-bis-(phenyl)-benzidine), s-TAD (2,2′,7,7′-tetrakis (N,N-dimethylamino)-9,9-spirofluorene) and MTDATA (4,4′,4″-Tris(N-3-methylphenyl-N-phenyl-amino)-triphenylamine). However, the present disclosure is not limited thereto.

In the meantime, a hole injection layer may be disposed between the first electrode 131 and the hole transport layer 132. The hole injection layer may be an organic layer for smoothly injecting a hole to the light emitting unit 133 from the first electrode 131. For instance, the hole injection layer may be formed of at least one selected from a group consisting of HAT-CN(dipyrazino[2,3-f: 2′,3′-h] quinoxaline-2,3,6,7,10.11-hexacarbonitrile), CuPc(phthalocyanine), and NPD (N,N′-bis(naphthalene-1-yl)-N,N′-bis(phenyl)-2,2′-dimethylbenzidine). However, the present disclosure is not limited thereto. The hole injection layer may be included or omitted according to a structure or a characteristic of the display device 100.

The light emitting unit 133 may be disposed on the hole transport layer 132. The light emitting unit 133 may be disposed on the hole transport layer 132 so as to overlap the first electrode 131. The light emitting unit 133 may be patterned between two banks 116 adjacent to each other, thereby forming a light emitting area. The light emitting unit 133 may include a material capable of emitting light of a specific color. For instance, the light emitting unit 133 may include a light emitting material capable of emitting red light, green light, blue light or yellowish green light. However, the present disclosure is not limited thereto. That is, the light emitting unit 133 may include a light emitting material capable of emitting light of other colors.

The electron transport layer 134 may be disposed on the light emitting unit 133.

The electron transport layer 134 may be an organic layer for transferring an electron to the light emitting unit 133. The electron transport layer 134 may be disposed as a single layer along a top surface of the light emitting unit 133 and the hole transport layer 132. The electron transport layer 134 may include a compound having an electron transport function. For instance, the electron transport layer 134 may be formed of at least one selected from a group consisting of metal quinolate, PBD(2-(4-biphenyl)-5-(4-tert-butylphenyl)-1,3,4oxadiazole), TAZ(3-(4-biphenyl) 4-phenyl-5-tert-butylphenyl-1,2,4-triazole), spiro-PBD and BCP (2,9-Dimethyl-4,7-diphenyl-1,10-phenanthroline). However, the present disclosure is not limited thereto.

The second electrode 135 may be disposed on the electron transport layer 134. The second electrode 135 may be a cathode electrode for supplying an electron to the light emitting unit 133, but the present disclosure is not limited thereto. The second electrode 135 may include or be formed of a metallic material such as magnesium (Mg), silver-magnesium (Ag:Mg). In case of a top emission type-display device which emits light in an upward direction, the second electrode 135 may be a transparent conductive oxide based on one or more of indium tin oxide ITO, indium zin oxide IZO, indium tin zinc oxide ITZO, zinc oxide ZnO and tin oxide TiO. However, the present disclosure is not limited thereto.

An electron injection layer may be disposed between the electron transport layer 134 and the second electrode 135. The electron injection layer may be an organic layer for smoothly injecting an electron to the light emitting unit 133 from the second electrode 135. The electron injection layer may be omitted when necessary.

A capping layer 117 may be disposed on the second electrode 135. The capping layer 117 may be formed of a material having a high refractive index and a high light absorption ratio so as to reduce diffused reflection of external light. For instance, the capping layer 117 may be an organic material layer formed of an organic material. However, the present disclosure is not limited thereto. That is, the capping layer 117 may be formed of an inorganic material. The capping layer 117 may be omitted when necessary.

A first inorganic encapsulation layer 141 is disposed on the capping layer 117. The first inorganic encapsulation layer 141 serves to block permeation of oxygen or moisture from the outside. The first inorganic encapsulation layer 141 may include or be formed of a silicon compound such as silicon nitride (SiNx) or silicon oxide (SiOx). However, the present disclosure is not limited thereto.

An organic encapsulation layer 142 is disposed on the first inorganic encapsulation layer 141. The organic encapsulation layer 142 serves to planarize an upper portion of the first inorganic encapsulation layer, and to compensate for a step due to foreign materials, a pinhole, or the like which may be present on a lower side of the organic encapsulation layer. The organic encapsulation layer 142 may be formed of an organic material such as acryl resin, epoxy resin, phenolic resin, polyamide resin, and polyimide resin. However, the present disclosure is not limited thereto.

Second inorganic encapsulation layers 143a and 143b are disposed on the organic encapsulation layer 142. The second inorganic encapsulation layers may be disposed as a single layer so as to cover components disposed at the lower side of the second inorganic encapsulation. The second inorganic encapsulation layers serve to block permeation of oxygen or moisture from the outside. The second inorganic encapsulation layers 143a and 143b may include or be formed of an inorganic material such as silicon nitride (SiNx) or silicon oxide (SiOx), and especially may include or be formed of silicon nitride (SiNx), for instance.

Referring to FIGS. 2 and 3, the second inorganic encapsulation layers 143a and 143b may have a different color according to their oxidation degree at each of the plurality of sub pixels SP. The second inorganic encapsulation layers 143a and 143b may have a yellow color system (in other words, may be presented as a yellow color) before oxidation, and may have a color change to a transparent white color as oxidation is performed. Here, oxidation of the second inorganic encapsulation layers 143a and 143b is accelerated by a temperature increase due to heat generation which occurs when the light emitting diode 130 is driven for a long time, energy absorption due to light emission of the light emitting diode 130, etc. Accordingly, an oxidation degree of each of the plurality of sub pixels SP may be variable according to a driving degree of the light emitting diode 130. For instance, as shown in FIG. 2, oxidation (or oxidation degree) of the second inorganic encapsulation layer 143a may be relatively small (or low) at some sub pixels SP where a driving frequency (the number of times) of the light emitting diode 130 is small (or low). Here, at the sub pixels SP where the oxidation (or oxidation degree) of the second inorganic encapsulation layer 143a is relatively small (or low), the second inorganic encapsulation layer 143a may have a yellow color system. On the other hand, as shown in FIG. 3, oxidation of the second inorganic encapsulation layer 143b may be relatively significant at some sub pixels SP where a driving frequency (the number of times) of the light emitting diode 130 is high. Here, at the sub pixels SP where the oxidation of the second inorganic encapsulation layer 143b is relatively significant, the second inorganic encapsulation layer 143b may have a transparent white color system (in other words, may be presented as a transparent white color).

Optical compensation layers 150a and 150b may be disposed on the second inorganic encapsulation layers 143a and 143b. The optical compensation layers 150a and 150b may block permeation of oxygen or moisture from the outside together with the second inorganic encapsulation layers 143a and 143b, and may solve an afterimage problem by compensating for a color change of the second inorganic encapsulation layers.

The optical compensation layer may be disposed as a single layer so as to cover components disposed at the lower side of the optical compensation layer. Here, at least one surface of the optical compensation layers 150a and 150b may contact a surface (for example, a top surface TS) of the second inorganic encapsulation layers 143a and 143b. For instance, a bottom surface BS of the optical compensation layers 150a and 150b may contact a top surface TS of the second inorganic encapsulation layers 143a and 143b.

The optical compensation layers 150a and 150b may include or be formed of a transition metal oxide. Here, a transition metal in the transition metal oxide may have an energy band gap of 2.18 eV˜3.10 cV, for instance, 2.48 cV˜2.76 eV. Also, the transition metal may include a transition metal of a blue color system. For instance, the transition metal may include at least one of cobalt (Co), cerium (Ce) and chrome (Cr). More specifically, the transition metal may include cobalt (Co) or cerium (Ce). Accordingly, the optical compensation layers 150a and 150b may be formed of at least one of a cobalt oxide, a cerium oxide and a chrome oxide. More specifically, the optical compensation layers 150a and 150b may be formed of a cobalt oxide or a cerium oxide.

The optical compensation layers 150a and 150b may be formed by depositing the aforementioned transition metal oxide on the second inorganic encapsulation layers 143a and 143b by a method of a physical vapor deposition (PVD), etc. However, the present disclosure is not limited thereto. Here, the transition metal oxide may actively undergo an oxidation reaction with external oxygen due to an oxygen deficiency structure. Thus, external oxygen is collected, which may suppress permeation of external oxygen to the second inorganic encapsulation layers 143a and 143b. This may reduce oxidation of the second inorganic encapsulation layers 143a and 143b.

Referring to FIGS. 2 and 3, the optical compensation layers 150a and 150b may have a different color according to their oxidation degree at each of the plurality of sub pixels SP. The optical compensation layers 150a and 150b may have a blue color system before oxidation, and may have a color change to a transparent white color as oxidation is performed. Here, oxidation of the optical compensation layers 150a and 150b is accelerated by a temperature increase due to heat generation which occurs when the light emitting diode 130 is driven for a long time, energy absorption due to light emission (luminance) of the light emitting diode 130, etc. Accordingly, an oxidation degree of each of the plurality of sub pixels SP may be variable according to a driving degree of the light emitting diode 130. For instance, as shown in FIG. 2, oxidation of the optical compensation layer 150a may be relatively low at some sub pixels SP where a driving frequency (the number of times) of the light emitting diode 130 is low. Here, the optical compensation layer 150a may have a blue color system. On the other hand, as shown in FIG. 3, oxidation of the optical compensation layer 150b may be relatively significant at some sub pixels SP where a driving frequency (the number of times) of the light emitting diode 130 is high. Here, at the sub pixels SP where the oxidation of the optical compensation layer 150b is relatively high, the optical compensation layer 150b may have a transparent white color system (in other words, may be presented as a transparent white color).

Thus, in the display device 100 according to an exemplary embodiment of the present disclosure, the second inorganic encapsulation layers 143a and 143b and the optical compensation layers 150a and 150b may have different colors at each of the plurality of sub pixels SP. For instance, at a sub pixel SP of FIG. 3 among the plurality of sub pixels SP, where oxidation has been performed relatively high or significant, the second inorganic encapsulation layer 143b and the optical compensation layer 150b may have a white color system. On the other hand, at a sub pixel SP of FIG. 2 among the plurality of sub pixels SP, where oxidation has been performed relatively less, the second inorganic encapsulation layer 143a may have a yellow color system and the optical compensation layer 150a may have a blue color system. Here, a color concentration (or intensity) of the second inorganic encapsulation layers 143a and 143b and the optical compensation layers 150a and 150b may be variable according to an oxidation degree. For instance, at some sub pixel SP among the plurality of sub pixels SP where oxidation has been performed relatively less, the second inorganic encapsulation layer 143a may have a yellow color system of a higher concentration and the optical compensation layer 150a may also have a blue color system of a higher concentration. A color concentration of each of the second inorganic encapsulation layer 143a and the optical compensation layer 150a may be lowered as oxidation is performed at each of the plurality of sub pixels SP. Here, the color concentration means a degree that a color is dark or light. For instance, a high color concentration means a dark color, and a low color concentration means a light color.

An organic light emitting diode generally has a structure including an anode, a cathode, and an organic material layer disposed between the anode and the cathode. The organic material layer generally has a multi-layer structure formed of different materials so as to enhance efficiency and stability of the organic light emitting diode. For instance, the organic material layer may consist of a hole injection layer, a hole transport layer, a light emitting layer, an electron transport layer, an electron injection layer, etc. In such a structure of the organic light emitting diode, when a voltage is applied between two electrodes (that is, the anode and the cathode), a hole from the anode and an electron from the cathode are injected into the organic material layer. When the injected hole and electron meet, exciton is formed. When the exciton falls to a bottom state, light is generated. Such an organic light emitting diode is a next generation light source having a self-luminance characteristic, and is more advantageous than a liquid crystal in the aspect of a viewing angle, a contrast, a response speed, power consumption, etc.

However, as aforementioned, the organic light emitting diode is very susceptible to water (H₂O) or oxygen (O₂) because it includes an organic material layer. More specifically, if water or oxygen is permeated into the organic light emitting diode including two electrodes and an organic light emitting layer disposed therebetween, a lifespan is shortened due to various types of defects such as a dark spot and pixel shrinkage due to electrode oxidation or deterioration of an organic material. The pixel shrinkage means a defect that a pixel is discolored to black from its edge, as an interface between the electrode and the organic light emitting layer is oxidized or degraded due to permeation of moisture or oxygen. When the pixel shrinkage continues for a long time, it may worsen into a dark spot that the pixel is entirely discolored to black, resulting in seriously influencing on the reliability of the organic light emitting display device.

Thus, in order to block permeation of moisture or oxygen to the organic light emitting diode, an encapsulation unit including a first inorganic encapsulation layer, an organic encapsulation layer and a second inorganic encapsulation layer is disposed on the organic light emitting diode. Here, the second inorganic encapsulation layer disposed at an uppermost part requires a physical property of a high density so as to enhance a moisture proof function, an oxygen proof function and a physical strength. To satisfy this, the second inorganic encapsulation layer is generally formed of a silicon-rich (Si-rich) inorganic material such as nitride silicon (SiNx). The Si-rich second inorganic encapsulation layer is generally yellowish because it absorbs light of a blue wavelength. Accordingly, a color coordinate shift of the organic light emitting display device is generated. Especially, an Si-rich inorganic material such as nitride silicon (SiNx) is oxidized by a temperature increase due to heat generation which occurs when the light emitting diode is driven for a long time, and energy absorption due to light emission. Further, the second inorganic encapsulation layer, a layer disposed at an uppermost part, is influenced the most by moisture or oxygen from the outside. Thus, the second inorganic encapsulation layer is more rapidly oxidized than other layers. Once the second inorganic encapsulation layer is oxidized, a moisture proof function is reduced and the second inorganic encapsulation layer is discolored to white from yellow.

The organic light emitting display device includes a plurality of sub pixels, and each of the plurality of sub pixels emits light of a different color of, for example, white, blue, green and red. The organic light emitting display device transmits images of various colors by combining the plurality of sub pixels which emit different colors with each other. When the organic light emitting display device transmits images, a luminance (light emission) frequency of each of the plurality of sub pixels is variable.

Since a luminance frequency of each of the plurality of sub pixels is variable, the number of times (frequency) of light which reaches the second inorganic encapsulation layer on the light emitting diode at each of the plurality of sub pixels is also variable. That is, the second inorganic encapsulation layer disposed at a sub pixel which emits light with a higher frequency is much influenced by light emitted from the light emitting diode, thereby having its oxidation accelerated. On the other hand, the second inorganic encapsulation layer disposed at a sub pixel which emits light with a lower frequency is less influenced by light emitted from the light emitting diode, thereby having its oxidation delayed. As aforementioned, the second inorganic encapsulation layer is discolored to white from yellow according to an oxidation degree. Thus, if an oxidation degree of the second inorganic encapsulation layer is variable at each of the plurality of sub pixels, a color of the second inorganic encapsulation layer is also variable at each of the plurality of sub pixels. That is, the second inorganic encapsulation layer disposed at a sub pixel which emits light with a higher frequency is white because it is much oxidized. On the other hand, the second inorganic encapsulation layer disposed at a sub pixel which emits light with a lower frequency is yellow because it is less oxidized. Like this, since the second inorganic encapsulation layer has a different color at each of the plurality of sub pixels, there is a problem that stains, which are non-restorative afterimages, occur.

Accordingly, the display device 100 according to an exemplary embodiment of the present disclosure includes optical compensation layers 150a and 150b having (or including) or being formed of a transition metal oxide, on the second inorganic encapsulation layers 143a and 143b. Here, external oxygen is collected by an oxygen deficiency structure of the transition metal oxide. This may result in delaying oxidation of the second inorganic encapsulation layers 143a and 143b. Accordingly, the reliability of an oxidization proof function and a moisture (water) proof function of the display device 100 may be enhanced.

Further, the display device 100 according to an exemplary embodiment of the present disclosure may reduce or minimize occurrence of non-restorative afterimages.

As aforementioned, a difference in an oxidation degree of the second inorganic encapsulation layers 143a and 143b at each of the plurality of sub pixels may be reduced by delaying oxidation of the second inorganic encapsulation layers 143a and 143b. This may reduce a difference in a color change of the second inorganic encapsulation layers 143a and 143b at each of the plurality of sub pixels. As a result, a driving afterimage may be improved.

As shown in FIG. 2, the display device 100 according to an exemplary embodiment of the present disclosure may include the optical compensation layer 150a disposed on the second inorganic encapsulation layer 143a and having a complementary color relation with the second inorganic encapsulation layer 143a. This may compensate for a color of the second inorganic encapsulation layer 143a viewed as yellow when not oxidized, to white. Accordingly, when the display device 100 is viewed in a non-oxidized state, a color of a corresponding region may be viewed as white. As shown in FIG. 3, while oxidation is performed, the second inorganic encapsulation layer 143b and the optical compensation layer 150b may have a white color as their color concentration becomes light (or low). This may improve afterimages due to discoloration of the second inorganic encapsulation layer 143b and the optical compensation layer 150b which occurs as the display device 100 is driven. That is, the second inorganic encapsulation layers 143a and 143b and the optical compensation layers 150a and 150b may be viewed as white at all sub pixels regardless of an oxidation degree. As a result, occurrence of non-restorative afterimages may be reduced or minimized.

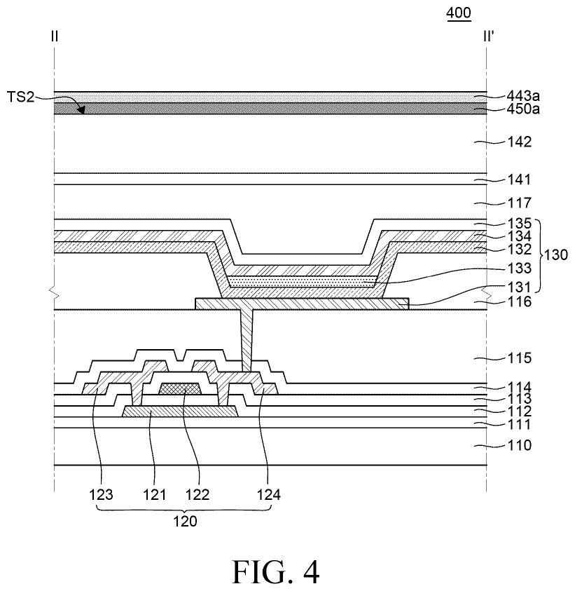

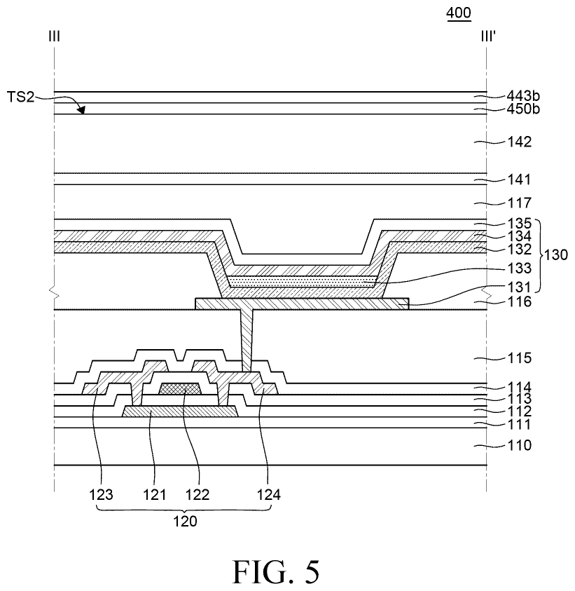

Hereinafter, a display device 400 according to another exemplary embodiment of the present disclosure will be explained with reference to FIGS. 4 and 5.

FIG. 4 is a cross-sectional view of a display device according to another exemplary embodiment of the present disclosure. FIG. 5 is a cross-sectional view of a display device according to another exemplary embodiment of the present disclosure. A sub pixel SP of FIG. 4 is a sub pixel SP in an initial state of the display device 400, or in an almost non-light emission state. A sub pixel SP of FIG. 5 is a sub pixel SP in a light emission state of the display device 400 for a significantly long time. As compared with the display device 100 of FIGS. 1 to 3, the display device 400 of FIGS. 4 and 5 has the same configurations except for a disposition order of second inorganic encapsulation layers 443a and 443b and optical compensation layers 450a and 450b. Thus, the same explanations will be omitted.

Referring to FIGS. 4 and 5, the display device 400 according to another exemplary embodiment of the present disclosure may include optical compensation layers 450a and 450b below second inorganic encapsulation layers 443a and 443b. More specifically, the optical compensation layers 450a and 450b may be disposed between an organic encapsulation layer 142 and the second inorganic encapsulation layers 443a and 443b. The optical compensation layers 450a and 450b may be disposed to entirely cover a top surface TS2 and a side surface (not shown) of the organic encapsulation layer 142. For instance, the optical compensation layers 450a and 450b may be disposed to have a larger area than the organic encapsulation layer 142.

The display device 400 according to another exemplary embodiment of the present disclosure may include the optical compensation layers 450a and 450b below the second inorganic encapsulation layers 443a and 443b. Under this configuration, heat or light emission energy generated from the light emitting diode 130 may be blocked from being transferred to the second inorganic encapsulation layers 443a and 443b. As a result, oxidation of the second inorganic encapsulation layers 443a and 443b may be delayed.

Further, in the display device 400 according to another exemplary embodiment of the present disclosure, peripheral (or ambient) oxygen is collected through the optical compensation layers 450a and 450b including or being formed of a transition metal oxide having an excellent oxygen collection function. As a result, oxidation of the second inorganic encapsulation layers 443a and 443b may be delayed. Further, since permeation of moisture or oxygen to the light emitting diode 130 is suppressed, the reliability of an oxidization proof function and a moisture proof function of the display device 400 may be enhanced.

As shown in FIG. 4, the display device 400 according to another exemplary embodiment of the present disclosure may include the second inorganic encapsulation layer 443a disposed on the optical compensation layer 450a and having a complementary color relation with the optical compensation layer 450a. This may compensate for a color of the second inorganic encapsulation layer 443a viewed as yellow when not oxidized, to white. Accordingly, a color coordinate shift of the display device 400 may be suppressed. Further, as shown in FIG. 5, while oxidation is performed, the optical compensation layer 450b and the second inorganic encapsulation layer 443b may have a transparent white color system (system (in other words, may be presented as a transparent white color). Under this configuration, the display device 400 according to an exemplary embodiment of the present disclosure may be viewed as a uniform color regardless of an oxidation degree of the second inorganic encapsulation layers 443a and 443b, at each of the plurality of sub pixels SP. This may reduce or minimize a color difference among the plurality of sub pixels SP.

The exemplary embodiments of the present disclosure can also be described as follows:

According to an aspect of the present disclosure, there is provided a display device. The display device comprises a substrate which includes a display area and a non-display area surrounding the display area, a light emitting element such as a light emitting diode on the display area (or disposed at the display area), a first inorganic encapsulation layer on the light emitting element, an organic encapsulation layer on the first inorganic encapsulation layer, a second inorganic encapsulation layer on the organic encapsulation layer; and an optical compensation layer, which is disposed on or below the second inorganic encapsulation layer, and includes or is formed of a transition metal oxide.

The light emitting element may be configured as an organic light emitting diode.

The optical compensation layer may be disposed on the second inorganic encapsulation layer and contact a top surface of the second inorganic encapsulation layer.

The optical compensation layer may be disposed between the organic encapsulation layer and the second inorganic encapsulation layer.

The optical compensation layer may contact a bottom surface of the second inorganic encapsulation layer.

The optical compensation layer may be disposed to entirely cover a top surface and a side surface of the organic encapsulation layer.

The optical compensation layer may be disposed to have a larger area than the organic encapsulation layer.

A transition metal in the transition metal oxide may have an energy band gap of 2.18 eV ˜3.10 eV.

The transition metal may have an energy band gap of 2.48 eV˜2.76 eV.

The transition metal oxide may include at least one of a cobalt oxide, a cerium oxide, a manganese oxide and a chrome oxide.

The transition metal oxide may include a cobalt oxide or a cerium oxide.

The optical compensation layer may have a complementary color relation with the second inorganic encapsulation layer.

The optical compensation layer may have a blue color system.

The second inorganic encapsulation layer may have a yellow color system.

The second inorganic encapsulation layer may include or be formed of silicon nitride (SiNx).

The optical compensation layer and the second inorganic encapsulation layer may be viewed as white regardless of an oxidation degree.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area and a non-display area adjacent to the display area;
a light emitting element on the display area;
a first inorganic encapsulation layer on the light emitting element;
an organic encapsulation layer on the first inorganic encapsulation layer;
a second inorganic encapsulation layer on the organic encapsulation layer; and
an optical compensation layer, which is disposed either on or below the second inorganic encapsulation layer, the optical compensation layer includes or is formed of a transition metal oxide.

2. The display device according to claim 1, wherein the light emitting element is configured as an organic light emitting diode.

3. The display device according to claim 1, wherein the optical compensation layer is disposed on the second inorganic encapsulation layer and contacts a top surface of the second inorganic encapsulation layer.

4. The display device according to claim 1, wherein the optical compensation layer is disposed between the organic encapsulation layer and the second inorganic encapsulation layer.

5. The display device according to claim 4, wherein the optical compensation layer contacts a bottom surface of the second inorganic encapsulation layer.

6. The display device according to claim 4, wherein the optical compensation layer is disposed to entirely cover a top surface and at least one side surface of the organic encapsulation layer.

7. The display device according to claim 4, wherein the optical compensation layer is disposed to have a larger area than the organic encapsulation layer.

8. The display device according to claim 1, wherein a transition metal in the transition metal oxide has an energy band gap of 2.18 eV˜3.10 eV.

9. The display device according to claim 5, wherein the transition metal has an energy band gap of 2.48 eV˜2.76 eV.

10. The display device according to claim 1, wherein the transition metal oxide includes at least one of a cobalt oxide, a cerium oxide, a manganese oxide, and a chrome oxide.

11. The display device according to claim 10, wherein the transition metal oxide includes either a cobalt oxide or a cerium oxide.

12. The display device according to claim 1, wherein the optical compensation layer has a complementary color relation with the second inorganic encapsulation layer.

13. The display device according to claim 1, wherein the optical compensation layer has a blue color system.

14. The display device according to claim 1, wherein the second inorganic encapsulation layer has a yellow color system.

15. The display device according to claim 1, wherein the second inorganic encapsulation layer includes or is formed of silicon nitride.

16. The display device according to claim 1, wherein the optical compensation layer and the second inorganic encapsulation layer are viewed as white regardless of an oxidation degree.

17. The display device according to claim 1, wherein the optical compensation layer is disposed to entirely cover a top surface of the organic encapsulation layer.
